(19) United States
(12) Patent Application Publication
(10) Pub. No.: US 2023/0008633 A1
(43) Pub. Date: Jan. 12, 2023

(54) SEMICONDUCTOR STRUCTURE AND METHOD FOR FORMING SEMICONDUCTOR STRUCTURE

(71) Applicant: CHANGXIN MEMORY TECHNOLOGIES, INC., Hefei City (CN)

(72) Inventors: TZUNG-HAN LEE, Hefei (CN); CHIH-CHENG LIU, Hefei (CN)

(73) Assignee: CHANGXIN MEMORY TECHNOLOGIES, INC., Hefei City (CN)

(21) Appl. No.: 17/807,725

(22) Filed: Jun. 19, 2022

Related U.S. Application Data
(63) Continuation of application No. PCT/CN2021/117255, filed on Sep. 8, 2021.

(30) Foreign Application Priority Data
Jul. 8, 2021 (CN) 202110773747.0

(51) Int. Cl. H01L 23/31; H01L 23/498

(52) U.S. Cl. CPC H01L 23/3107; H01L 23/49827

(57) ABSTRACT

A semiconductor structure includes a Through Silicon Via (TSV) and a protective ring disposed outside the TSV; the protective ring includes at least two protective layers arranged in parallel and surrounding the TSV; each of the protective layers includes a first protective structure and second protective structures disposed surrounding the first protective structure; the first protective structure is a polygonal structure; a number of sides of the polygonal structure is greater than or equal to 4; and the second protective structures are disposed on an inner side and an outer side of each corner area of the polygonal structure.

### CROSS-REFERENCE TO RELATED APPLICATIONS

This application is a continuation of International Application No. PCT/CN2021/117255 filed on Sep. 8, 2021, which claims priority to Chinese Patent Application No. 202110773747.0 filed on Jul. 8, 2021. The disclosures of the above-referenced applications are hereby incorporated by reference in their entirety.

### BACKGROUND

With the development of a semiconductor technology, the critical dimension of an integrated circuit is shrinking, and the interconnection density of devices is increasing. Traditional two-dimensional packaging can no longer meet industry requirements. Therefore, vertical interconnection stacked packaging based on a Through Silicon Via (TSV) technology gradually leads the development trend of a packaging technology with its key technical advantages of short-distance interconnection and high-density integration.

### SUMMARY

The embodiments of the disclosure relate, but are not limited, to a semiconductor structure and a method for forming the semiconductor structure.

The embodiments of the disclosure provide a semiconductor structure, including a TSV and a protective ring disposed outside the TSV. The protective ring includes at least two protective layers arranged in parallel and surrounding the TSV. Each of the protective layers includes a first protective structure and second protective structures disposed surrounding the first protective structure. The first protective structure is a polygonal structure. A number of sides of the polygonal structure is greater than or equal to 4. The second protective structures are disposed on an inner side and an outer side of each corner area of the polygonal structure.

The embodiments of the disclosure further provide a method for forming a semiconductor structure, including: a protective ring is formed, where the protective ring includes at least two protective layers arranged in parallel, each of the protective layers includes a first protective structure and second protective structures disposed surrounding the first protective structure, the first protective structure is a polygonal structure, a number of sides of the polygonal structure is greater than or equal to 4, and the second protective structures are disposed on an inner side and an outer side of each corner area of the polygonal structure; and a TSV is formed on the inner side of the protective ring, to enable the protective ring to surround the TSV.

### BRIEF DESCRIPTION OF THE DRAWINGS

In the drawings (which are not necessarily drawn to scale), similar drawing signs may describe similar parts in different views. Similar drawing signs with different letter suffixes may represent different examples of similar parts. The drawings generally illustrate the various embodiments discussed herein by way of examples rather than limitation.

FIG. 1 is a top view of a semiconductor structure in some implementations.

FIG. 2A is a schematic structural diagram of a semiconductor structure according to some embodiments of the present disclosure.

FIG. 2B is a first overhead schematic structural diagram of a semiconductor structure according to some embodiments of the present disclosure.

FIG. 2C is a second overhead schematic structural diagram of a semiconductor structure according to some embodiments of the present disclosure.

FIG. 2D is a third overhead schematic structural diagram of a semiconductor structure according to some embodiments of the present disclosure.

FIG. 2E is a fourth overhead schematic structural diagram of a semiconductor structure according to some embodiments of the present disclosure.

FIG. 2F is an overhead schematic structural diagram of a protective ring according to some embodiments of the present disclosure.

FIG. 3A is a schematic structural diagram of a semiconductor structure according to some embodiments of the present disclosure.

FIG. 3B is a sectional view in a first direction of a semiconductor structure according to some embodiments of the present disclosure.

FIG. 3C is a sectional view in a second direction of a semiconductor structure according to some embodiments of the present disclosure.

FIG. 3D is a schematic structural diagram of a metal conductive structure according to some embodiments of the present disclosure.

FIG. 4 is a schematic structural diagram of a method for forming a semiconductor structure according to some embodiments of the present disclosure.

FIG. 5A is a first process flowchart of a method for forming a semiconductor structure according to some embodiments of the present disclosure.

FIG. 5B is a second process flowchart of a method for forming a semiconductor structure according to some embodiments of the present disclosure.

FIG. 5C is a third process flowchart of a method for forming a semiconductor structure according to some embodiments of the present disclosure.

FIG. 5D is a fourth process flowchart of a method for forming a semiconductor structure according to some embodiments of the present disclosure.

FIG. 5E is a fifth process flowchart of a method for forming a semiconductor structure according to some embodiments of the present disclosure.

### DETAILED DESCRIPTION

Exemplary implementations of the disclosure will be described below more comprehensively with reference to the drawings. Although the exemplary implementations of the disclosure are shown in the drawings, it should be understood that, the disclosure may be implemented in various forms and should not be limited by the specific implementations elaborated herein. On the contrary, these implementations are provided to enable a more thorough understanding of the disclosure and to fully convey the scope of the disclosure to those skilled in the art.

In the following description, a large number of specific details are given in order to provide a more thorough understanding of the disclosure. However, it will be apparent to those skilled in the art that the disclosure may be implemented without one or more of these details. In other examples, in order to avoid confusion with the disclosure, some technical features known in the art are not described. That is, all the features of the actual embodiments are not described herein, and the known functions and structures are not described in detail.

In the drawings, the sizes of layers, areas and elements and their relative sizes may be exaggerated for clarity. The same drawing signs represent the same elements throughout.

It is to be understood that description that an element or layer is “above”, “adjacent to”, “connected to”, or “coupled to” another element or layer may refer to that the element or layer is directly above, adjacent to, connected to or coupled to the other element or layer, or there may be an intermediate element or layer. On the contrary, description that an element is “directly on”, “directly adjacent to”, “directly connected to” or “directly coupled to” another element or layer refers to that there is no intermediate element or layer. It is to be understood that, although various elements, components, areas, layers and/or parts may be described with terms “first”, “second”, “third”, etc., these elements, components, areas, layers and/or parts should not be limited to these terms. These terms are used only to distinguish one element, component, area, layer or part from another element, component, area, layer or part. Therefore, a first element, component, area, layer or part discussed below may be represented as a second element, component, area, layer or part without departing from the teaching of the disclosure. However, when the second element, component, area, layer or part is discussed, it does not mean that the first element, component, area, layer or part must exist in the disclosure.

In order to conveniently describe, spatially relational terms such as “below”, “under”, “lower”, “beneath”, “above”, and “upper” may be used herein for describing a relationship between one element or feature and another element or feature illustrated in the figure. It is to be understood that, in addition to the orientation shown in the figures, the spatially relational terms are intended to further include different orientations of devices in use and operation. For example, if the devices in the figures are turned over, elements or features described as being “under” or “beneath” or “below” other elements or features will be oriented to be “on” the other elements or features. Therefore, the exemplary terms “under” and “below” may include both upper and lower orientations. The device may include otherwise orientation (rotation by 90 degrees or in other orientations) and the spatial descriptors used herein may be interpreted accordingly.

The terms used herein are intended only to describe specific embodiments and are not a limitation of the disclosure. As used herein, singular forms “a/an”, “one”, and “the” may also be intended to include the plural forms, unless otherwise specified forms in the context. It is also to be understood that, when terms “composed of” and/or “including” are used in this specification, the presence of the features, integers, steps, operations, elements, and/or components may be determined, but the presence or addition of one or more other features, integers, steps, operations, elements, components, and/or groups is also possible. As used herein, term “and/or” includes any and all combinations of the related listed items.

TSVs in some implementations are usually filled with metallic copper as conductive columns. However, due to different thermal expansion coefficients of copper and substrate silicon, or excessive stress caused by lattice mismatch, cracks will occur in a device structure, and the structure of a semiconductor device will be damaged.

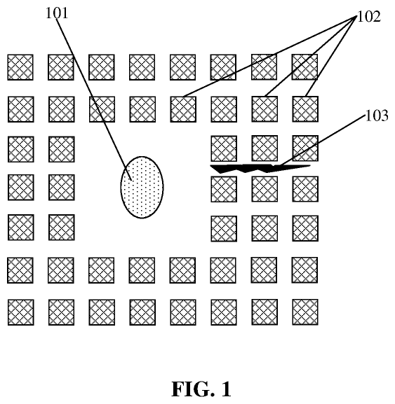

A vertical interconnection stacked packaging based on a TSV interconnection technology is to stack two or more semiconductor chips together and implement signal transmission between the semiconductor chips through the TSV. However, in some implementations, the thermal expansion coefficient of a copper conductive column filled with the TSV is different from that of silicon in a silicon substrate, which will cause cracks in a device structure. As illustrated in FIG. 1, it is a top view of a semiconductor structure in some implementations. It can be seen that, in some implementations, due to the stress generated by a TSV 101, cracks 103 will be generated in an active area (AA)/Gate conductive layer/metal layer (M0) 102 in a semiconductor device, resulting in damage of the semiconductor structure.

Based on the above problems in some implementations, the embodiments of the disclosure provide a semiconductor structure and a method for forming the semiconductor structure, which may resist the stress generated by a TSV and protect the semiconductor structure from damage.

The embodiments of the disclosure provide a semiconductor structure, including a TSV and a protective ring disposed outside the TSV. The protective ring includes at least two protective layers arranged in parallel and surrounding the TSV. Each of the protective layers includes a first protective structure and second protective structures disposed surrounding the first protective structure. The first protective structure is a polygonal structure. A number of sides of the polygonal structure is greater than or equal to 4. The second protective structures are disposed on an inner side and an outer side of each corner area of the polygonal structure.

The specific implementations of the disclosure are described in detail below in combination with the drawings. When the embodiments of the disclosure are described in detail, for ease of illustration, a schematic diagram will be locally enlarged not in general proportion and the schematic diagram is only an example, which shall not limit the scope of protection of the disclosure.

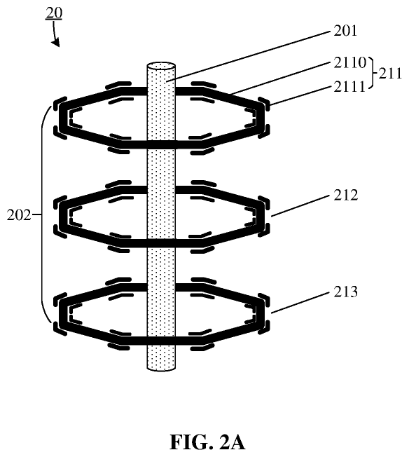

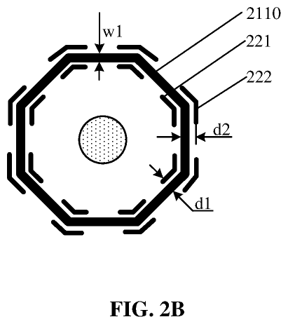

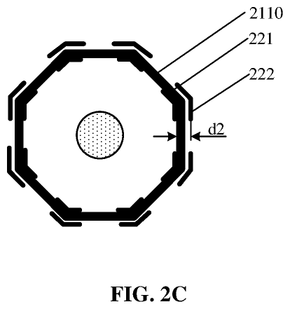

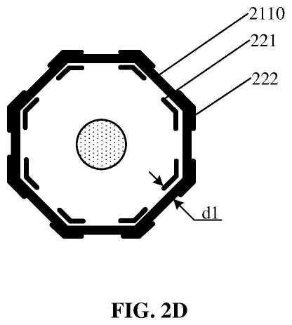

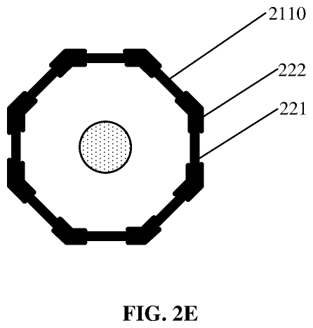

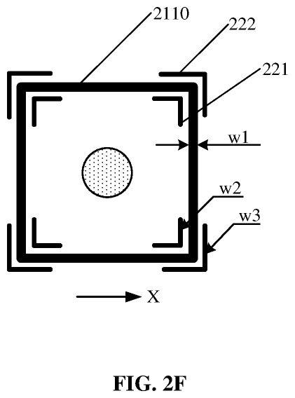

FIG. 2A is an optional schematic structural diagram of a semiconductor structure according to an embodiment of the present disclosure. As illustrated in FIG. 2A, the semiconductor structure 20 includes a TSV 201 and a protective ring 202 disposed outside the TSV 201, and the protective ring 202 includes at least two protective layers in parallel and surrounding the TSV 201, which are a protective layer 211, a protective layer 212 and a protective layer 213. Each protective layer includes a first protective structure and second protective structures disposed surrounding the first protective structure. For example, the protective layer 211 includes a first protective structure 2110 and second protective structures 2111. The first protective structure 2110 is an octagonal structure, and the second protective structures 2111 are disposed on an inner side and an outer side of each corner area of the octagonal structure.

In the embodiments of the disclosure, the first protective structure is a polygonal structure. A number of sides of the polygonal structure is greater than or equal to 4. For example, the first protective structure may be a quadrilateral structure, a hexagonal structure or a dodecagonal structure. Since the first protective area is a polygonal structure, the first protective structure has a corner area, and will bear greater stress in the corner area. Based on this, the second protective structure is disposed in the corner area of the first protective structure to strengthen the corner area of the first protective structure, so that the corner area of the first protective structure can bear greater stress.

In some embodiments, the second protective structure disposed on an inner side of each corner area of the polygonal structure is in contact with the corner area or separated from the corner area by a first preset distance. The second protective structure disposed on an outer side of each corner area of the polygonal structure is in contact with the corner area or separated from the corner area by a second preset distance. The first preset distance or the second preset distance is 0.1 microns to 2 microns.

FIGS. 2B-2E are optional overhead schematic structural diagrams of a semiconductor structure according to an embodiment of the present disclosure. As illustrated in FIGS. 2B-2E, the second protective structure 221 disposed on the inner side of each corner area of the polygonal structure 2110 is in contact with the corner area (as illustrated in FIGS. 2C and 2E) or separated from the corner area by a first preset distance d1 (as illustrated in FIGS. 2B and 2D), and the second protective structure 222 disposed on the outer side of each corner area of the polygonal structure 2110 is in contact with the corner area (as illustrated in FIGS. 2D and 2E) or separated from the corner area by a second preset distance d2 (as illustrated in FIGS. 2B and 2C). In the embodiments of the disclosure, the first preset distance d1 and the second preset distance d2 may be the same or different.

In some embodiments, the first protective structure has a first preset size in a first direction. The first preset size is 0.3 microns to 2 microns. The second protective structure has a second preset size in the first direction. The second preset size is 0.1 microns to 2 microns. The first direction is perpendicular to the extension direction of the TSV.

Any direction perpendicular to the extension direction of the TSV is defined as the first direction. For example, the first direction may be the X-axis direction. FIG. 2F is an optional overhead schematic structural diagram of a protective ring according to an embodiment of the present disclosure. As illustrated in FIG. 2F, the first protective structure 2110 has a first preset size w1 in the X-axis direction, and the second protective structure includes a second protective structure 221 disposed on the inner side of each corner area of the first protective structure 2110 and a second protective structure 222 disposed on the outer side of each corner area of the first protective structure 2110. The second protective structure has a second preset size w2/w3 in the X-axis direction.

In some embodiments, the first preset size w1 may be greater than the second preset size w2/w3, or may be less than or equal to the second preset size w2/w3. The size w2 of the second protective structure 221 in the X-axis direction may be greater than the size w3 of the second protective structure 222 in the X-axis direction, or may be less than or equal to the size w3 of the second protective structure 222 in the X-axis direction.

It is to be noted that, the size of the first protective structure in each protective layer in the first direction may be the same or different. In each protective layer, the size of the second protective layer in the first direction may be the same or different. In each protective layer, the relative position relationship between the second protective structure and the first protective structure may be the same or different.

In the embodiments of the disclosure, the relative position relationship between the second protective structure and the first protective structure includes the following two types: one of the types is that the second protective structure is in contact with the first protective structure, and the other of the types is that a preset distance is provided between the second protective structure and the first protective structure.

In some embodiments, the protective ring further includes connecting layers connecting all of the protective layers. Each connecting layer connects adjacent polygonal structures, and each connecting layer is located in a projection area of each corner area of the polygonal structure.

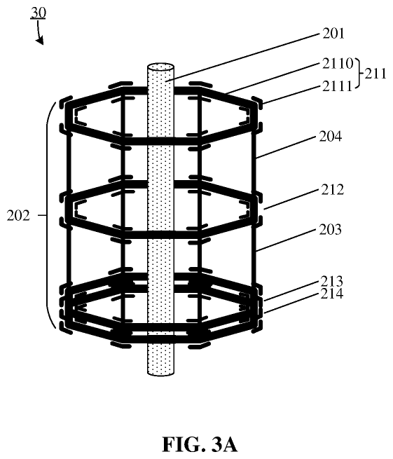

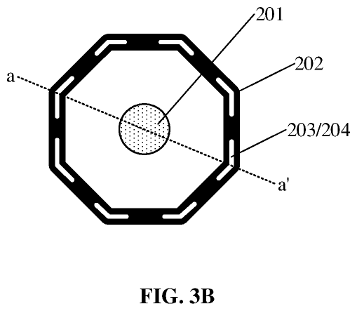

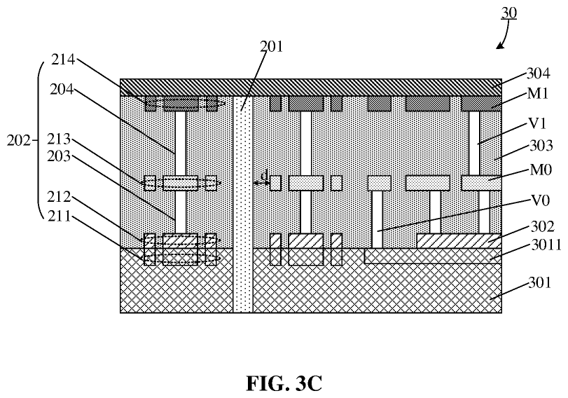

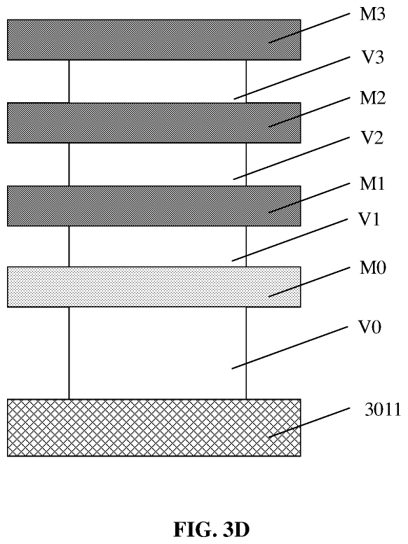

FIG. 3A is an optional schematic structural diagram of a semiconductor structure according to an embodiment of the present disclosure. As illustrated in FIG. 3A, the semiconductor structure 30 includes a TSV 201 and a protective ring disposed outside the TSV 201, the protective ring includes at least two protective layers 211, 212, 213 and 214 arranged in parallel and surrounding the TSV, each of the protective layers includes a first protective structure and a second protective structure, and the first protective structure is a polygonal structure. The protective ring further includes connecting layers 203 and 204 connecting all of the protective layers. The connecting layers 203 and 204 connect adjacent polygonal structures, and the connecting layers 203 and 204 are disposed in a projection area of each corner area of the polygonal structure.

In some embodiments, the polygonal structures of the at least two protective layers have projection areas in the extension direction of the TSV coincided with one another. A projection area of the connecting layer in the extension direction of the TSV is located in a projection area of two adjacent protective layers in the extension direction of the TSV.

FIGS. 3B and 3C are sectional views in different directions of a semiconductor structure according to an embodiment of the present disclosure. The semiconductor structure provided in the embodiments of the disclosure will be further described below in detail with reference to FIGS. 3B and 3C.

FIG. 3B is a sectional view of FIG. 3A along a direction perpendicular to the TSV, and FIG. 3C is a sectional view of FIG. 3B along a dotted line a-a′. As illustrated in FIGS. 3B and 3C, the semiconductor structure 30 includes a substrate 301, and the TSV 201 and the protective ring 202 are formed on the substrate 301.

In the embodiments of the disclosure, the substrate 301 may be a silicon substrate. In other embodiments, the substrate may include other semiconductor elements such as germanium (Ge), or semiconductor compounds such as silicon carbide (SiC), gallium arsenide (GaAs), gallium phosphide (GaP), indium phosphide (InP), indium arsenide (InP) or indium antimonide (InSb), or other semiconductor alloys such as silicon germanium (SiGe), gallium arsenide phosphide (GaAsP), indium aluminum arsenide (AlInAs), gallium aluminum arsenide (AlGaAs), indium gallium arsenide (GaInAs), indium gallium phosphide (GaInP), and/or indium gallium arsenide phosphide (GaInAsP) or a combination thereof.

In some embodiments, the diameter of the TSV 201 is between 2 microns and 6 microns. For example, it may be 3 microns.

The protective ring 202 is disposed outside the TSV 201 in a surrounding manner. The protective ring 202 includes at least two parallel protective layers, which are a protective layer 211, a protective layer 212, a protective layer 213 and a protective layer 214. Each protective layer includes a first protective structure and second protective structures disposed surrounding the first protective structure. The first protective structure is a polygonal structure. Therefore, each first protective structure has a corner area. For example, the first protective structure may be a quadrilateral structure or an octagonal structure.

It is to be noted that, the size of the first protective structure in each of the protective layers in a direction perpendicular to the extension direction of the TSV may be the same or different. The size of the second protective structure in each of the protective layers in a direction perpendicular to the extension direction of the TSV may be the same or different. In each protective layer, the relative position relationship between the second protective structure and the first protective structure may be the same or different.

In the embodiments of the disclosure, the relative position relationship between the second protective structure and the first protective structure includes the following two types: one of the types is that the second protective structure is in contact with the first protective structure, and the other of the types is that a preset distance is provided between the second protective structure and the first protective structure.

Also referring to FIGS. 3B and 3C, in some embodiments, the protective ring also includes connecting layers 203 and 204, the connecting layers 203 and 204 connect two adjacent polygonal structures (i.e. connect two adjacent first protective structures), and the connecting layers 203 and 204 are disposed in a projection area of each corner area of the polygonal structure.

Also referring to FIG. 3C, in some embodiments, the semiconductor structure further includes a metal conductive structure. The metal conductive structure includes at least two metal layers M0 and M1 and at least one contact hole V0 and V1 connecting two adjacent metal layers. The metal layers M0 and M1 and the contact holes V0 and V1 are alternately distributed along the extension direction of the TSV.

It is to be noted that, FIG. 3B is a top view of the semiconductor structure in the layer of the contact hole V0 or the contact hole V1 in FIG. 3A. At this time, the connecting layers 303 and 304 are disposed in a projection area of each corner area of the polygonal structure.

In some embodiments, part of the protective layers of the protective ring and the metal layers are formed simultaneously in a same process step. The connecting layers of the protective ring and the contact hole are formed simultaneously in a same process step. For example, when the metal layers M0 and M1 are formed, the protective layers 213 and 214 are formed simultaneously, and when the contact holes V0 and V1 are formed, the connecting layer 203 and the connecting layer 204 are formed simultaneously. The contact hole V0 is configured to connect the substrate 301 and the metal layer M0.

Also referring to FIG. 3C, in some embodiments, the semiconductor structure also includes an active device 302 formed on a buried metal layer 3011 of the substrate 301, and the TSV 201 is configured to perform signal transmission between the active device 302 and other devices.

In the embodiments of the disclosure, the active device may be a memory such as a Dynamic Random Access Memory (DRAM) or a Static Random-Access Memory (SRAM). In other embodiments, the active device may be a logic chip.

Also referring to FIG. 3C, in some embodiments, the protective ring 202 also includes a protective layer 211 formed simultaneously with the buried metal layer 3011 in a same process step and a protective layer 212 formed simultaneously with a gate conductive layer of the active device 302 in a same process step.

In the embodiments of the disclosure, the protective layers 213 and 214 respectively include the same material with the metal layers M0 and M1. For example, they may be made of the same material. In some embodiments, the material of the metal layer M0 may be tungsten, and the material of the metal layer M1 may be copper. The protective layer 211 has the same material with the buried metal layer 3011. For example, they may be made of the same material. In some embodiments, the material of the buried metal layer may be silicon. The protective layer 212 has the same material with the gate conductive layer. For example, they may be made of the same material. In some embodiments, the material of the gate conductive layer may be tungsten. The material of the connecting layers 203 and 204 are the same as the material filling the contact holes V0 and V1. For example, the material may be tungsten.

In the embodiments of the disclosure, the metal conductive structure and the part of protective ring and the connecting layer formed simultaneously are disposed in a dielectric layer 303 on a surface of a substrate. Herein, the dielectric layer 303 may be any insulating layer, such as a silicon oxide layer or a silicon oxynitride layer.

Also referring to FIG. 3C, in the embodiments of the disclosure, a gap d is provided between an outer wall of the TSV 201 and an inner wall of the protective ring 202, and the size of the gap is between 1 micron and 10 microns.

Also referring to FIG. 3C, in some embodiments, the semiconductor structure 30 also includes a covering layer 304, which at least covers a surface of the TSV 201 and a surface of the protective ring 202 and is configured to protect the TSV and the protective ring. In the embodiments of the disclosure, the covering layer 304 also covers a surface of the metal conductive structure and is configured to protect the metal conductive structure.

In some embodiments, the covering layer may be any kind of insulating layer, such as a silicon oxide layer, a silicon nitride layer or phosphorus silicon glass.

It is to be noted that, the covering layer 304 is not a single-layer structure, which is formed by multi-layer insulating materials in multiple process steps.

It is to be noted that, in the embodiments of the disclosure, only some metal conductive layers are listed exemplarily. In the actual implementation process, the number of layers of metal layers and the number of contact holes contained of the metal conductive structure are not limited to those shown in FIG. 3C.

FIG. 3D is an optional schematic structural diagram of a metal conductive structure according to an embodiment of the present disclosure. As illustrated in FIG. 3D, the metal conductive structure includes at least two metal layers M0, M1, M2 and M3 and at least one contact hole V0, V1, V2 and V3 connecting two adjacent metal layers, and the metal layer M0 is connected to a semiconductor buried metal layer 3011 through the contact hole V0.

A semiconductor structure provided in the embodiments of the disclosure includes a TSV and a protective ring disposed outside the TSV. The protective ring includes at least two protective layers arranged in parallel and surrounding the TSV. Each of the protective layers includes a first protective structure and second protective structures disposed surrounding the first protective structure. The first protective structure is a polygonal structure. A number of sides of the polygonal structure is greater than or equal to 4. The second protective structures are disposed on an inner side and an outer side of each corner area of the polygonal structure. Since the periphery of the TSV in the embodiment of the disclosure is provided with at least two protective rings arranged in parallel, the stress generated by the TSV may be resisted through the protective rings, and the semiconductor structure is prevented from being damaged.

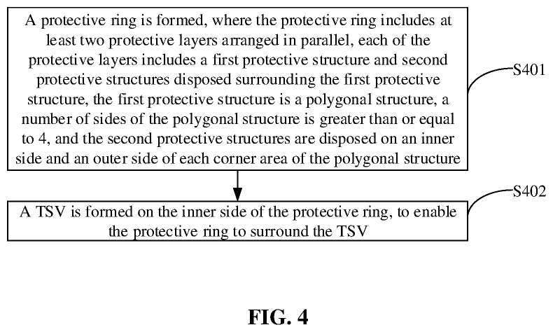

Besides, the embodiments of the disclosure also provide a method for forming a semiconductor device. FIG. 4 is an optional schematic structural diagram of a method for forming a semiconductor device according to an embodiment of the present disclosure. As illustrated in FIG. 4, the method includes steps S401 to S402.

In S401, a protective ring is formed, where the protective ring includes at least two protective layers arranged in parallel, each of the protective layers includes a first protective structure and second protective structures disposed surrounding the first protective structure, the first protective structure is a polygonal structure, a number of sides of the polygonal structure is greater than or equal to 4, and the second protective structures are disposed on an inner side and an outer side of each corner area of the polygonal structure.

In S402, a TSV is formed on the inner side of the protective ring, to enable the protective ring to surround the TSV.

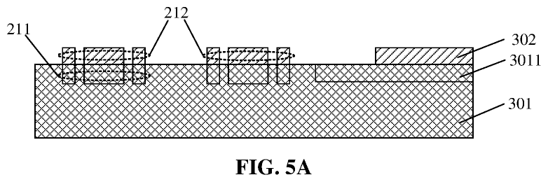

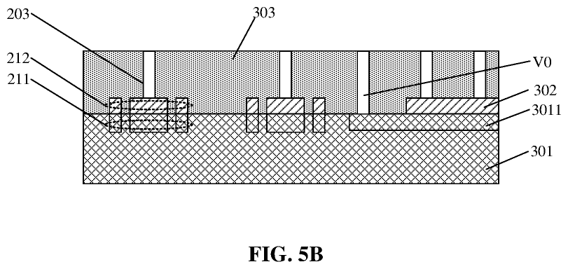

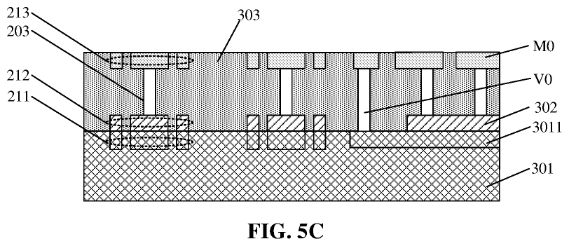

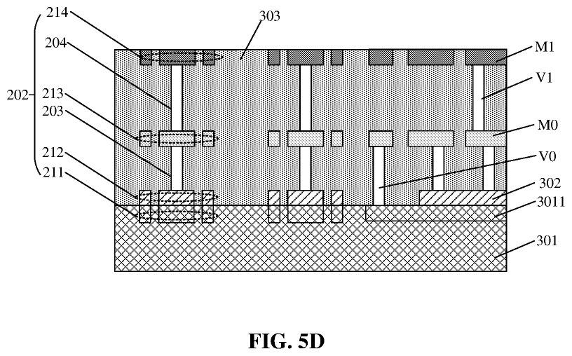

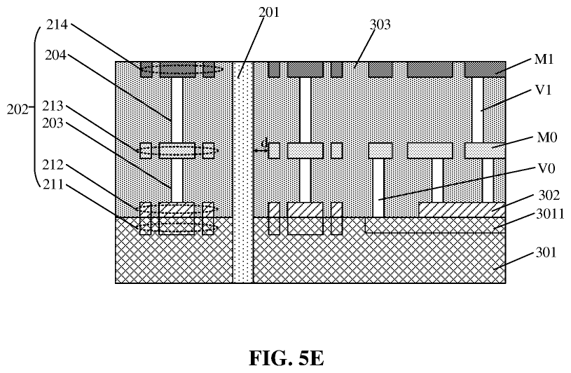

FIGS. 5A-5E are process flowcharts of a method for forming a semiconductor structure according to an embodiment of the present disclosure. A method for forming a semiconductor structure in the embodiments of the disclosure will be described below in detail in combination with FIGS. 5A-5E.

At first, referring to FIGS. 5A-5D, S401 is performed to form a protective ring.

The protective ring 202 includes at least two parallel protective layers, which are a protective layer 211, a protective layer 212, a protective layer 213 and a protective layer 214. Each protective layer includes a first protective structure and second protective structures disposed surrounding the first protective structure, the first protective structure is a polygonal structure, a number of sides of the polygonal structure is greater than or equal to 4, therefore, each first protective structure has a corner area, and the second protective structures are disposed on an inner side and outer side of each corner area of the polygonal structure.

In some embodiments, S401 may be implemented through the following steps.

At least two polygonal structures are formed sequentially.

The second protective structures each being in contact with a respective one of the corner areas or spaced at a first preset distance from the corner area is formed on an inner side of the corner area of each of the polygonal structures.

The second protective structures each being in contact with a respective one of the corner areas or spaced at a second preset distance from the corner area is formed on an outer side of the corner area, and the first preset distance or the second preset distance is 0.1 microns to 2 microns.

In some embodiments, the method for forming the semiconductor structure further includes: after the protective ring is formed, connecting layers connecting all of the protective layers are formed in a projection area of each corner area of the polygonal structure, and the connecting layers connect adjacent polygonal structures.

Referring to FIG. 5D, the connecting layers 203 and 204 connect adjacent protective layers 212, 213 and 214, and the connecting layers 203 and 204 are disposed in projection areas of the protective layers 213 and 214 respectively.

In some embodiments, the polygonal structures of the at least two protective layers have projection areas in the extension direction of the TSV coincided with one another. A projection area of the connecting layer in the extension direction of the TSV is located in a projection area of two adjacent protective layers in the extension direction of the TSV.

Also referring to FIG. 5D, in the embodiments of the disclosure, the semiconductor structure further includes a metal conductive structure. The metal conductive structure includes at least two metal layers M0 and M1 and at least one contact hole V0 and V1 connecting two adjacent metal layers. The metal layers M0 and M1 and the contact holes V0 and V1 are alternately distributed.

In some embodiments, a metal conductive structure is formed while the protective ring 202 is formed. Specifically, protective layers 213 and 214 of the protective ring and metal layers M0 and M1 of the metal conductive structure are formed simultaneously in a same process step. The connecting layers 203 and 204 of the protective ring and contact holes V0 and V1 of the metal conductive structure are formed simultaneously in a same process step.

Also referring to FIG. 5D, in the embodiments of the disclosure, the semiconductor structure further includes an active device 302 disposed in a buried metal layer 3011. A protective layer 212 of the protective ring and a gate conductive layer of the active device are formed simultaneously in a same process step, and the protective layer 211 and the buried metal layer 3011 are formed simultaneously in a same process step.

Then, the manufacturing process of the protective ring 202, the buried metal layer 3011, the active device 302 and the metal conductive structure is described in detail in combination with FIGS. 5A-5E. It is to be noted that, the manufacturing process described below is only an example, and other methods may be used to form the protective ring, the buried metal layer, the active device and the metal conductive structure.

As illustrated in FIG. 5A, a substrate 301 is provided, a buried metal layer 3011 is formed on the substrate, and an active device 302 is formed in the buried metal layer 3011. Herein, the protective layer 211 of the protective ring is formed while the buried metal layer 3011 is formed, and the protective layer 212 of the protective ring is formed while the gate conductive layer of the active device 302 is formed.

In the embodiments of the disclosure, the substrate 301 may be a silicon substrate. In other embodiments, the substrate may include other semiconductor elements such as germanium, or semiconductor compounds such as silicon carbide, gallium arsenide, gallium phosphide, indium phosphide, indium arsenide or indium antimonide, or other semiconductor alloys such as silicon germanium, gallium arsenide phosphide, indium aluminum arsenide, gallium aluminum arsenide, indium gallium arsenide, indium gallium phosphide, and/or indium gallium arsenide phosphide or a combination thereof.

In the embodiments of the disclosure, the active device may be a memory, such as a DRAM or SRAM. In other embodiments, the active device may be a logic chip.

As illustrated in FIG. 5B, a dielectric layer 303 is formed on a surface of the substrate 301, and a connecting layer 203 and a contact hole V0 are formed in the dielectric layer. Specifically, a through hole penetrating through the dielectric layer is formed, and the through hole is filled with a conductive material such as W, to form the connecting layer 203 and the contact hole V0.

As illustrated in FIG. 5C, a protective layer 213 electrically connected with the connecting layer 203 and a metal layer M0 electrically connected with the contact hole V0 are formed. Specifically, a dielectric layer 303 is formed, the dielectric layer is patterned, and the protective layer 213 and the metal layer M0 are formed in the patterned dielectric layer 303.

As illustrated in FIG. 5D, a connecting layer 204, a contact hole V1, a protective layer 214 electrically connected with a connecting layer 203, and a metal layer M1 electrically connected with a contact hole V1 are formed. In the embodiments of the disclosure, the process of forming the connecting layer 204 and the contact hole V1 is the same as that of forming the connecting layer 203 and the contact hole V0 in the above embodiments, and the process of forming the protective layer 214 and the metal layer M1 is the same as that of forming the protective layer 213 and the metal layer M0 in the above embodiments.

Then, referring to FIG. 5E, S402 is performed to form a TSV on the inner side of the protective ring, to enable the protective ring to surround the TSV.

In some embodiments, the TSV is specifically formed through the following steps.

A photoresist layer is formed on a surface of the dielectric layer.

The photoresist layer is patterned to form a window, and the window exposes a surface of the dielectric layer.

The dielectric layer and the substrate are etched through the window to form a blind hole structure in the substrate.

A buffer layer, a barrier layer, a seed layer and a conductive layer are sequentially formed in the blind hole structure.

The bottom of the substrate is thinned, so that the blind hole structure penetrates through the substrate to form the TSV, a top metal contact layer is formed at the top of the conductive layer, and a bottom metal contact layer is formed at the bottom of the conductive layer.

In some embodiments, for example, the buffer layer may be SiO₂, which is configured to protect the substrate from damage. The material of the barrier layer may be metallic tantalum, tantalum nitride or titanium nitride, and the barrier layer is configured to prevent the diffusion of the metal material of the conductive layer subsequently filled in the TSV. The metal material of the conductive layer may be any conductive metal, such as tungsten (W), cobalt (CO), copper (Cu) and aluminum (AL), such as copper metal. Specifically, a copper conductive layer may be formed by depositing a copper seed crystal layer (i.e. seed layer) through Physical Vapor Deposition (PVD) and then electroplating copper. The TSV provides conductivity through the top metal contact layer and the bottom metal contact layer in the conductive layer.

As illustrated in FIG. 5D, in the embodiments of the disclosure, a TSV 201 is formed on the inner side of the protective ring 202.

In some embodiments, the diameter of the TSV 201 may be between 2 microns and 6 microns. For example, it may be 3 microns.

Also referring to FIG. 5D, in the embodiments of the disclosure, a gap d is provided between an outer wall of the TSV 201 and an inner wall of the protective ring 202, and the size of the gap is between 1 micron and 10 microns.

In some embodiments, the semiconductor device also includes a covering layer (not shown in the figure). The method for forming the semiconductor device also includes: the covering layer is formed, and the covering layer at least covers the TSV and the protective ring.

In some embodiments, the covering layer may be any kind of insulating layer, such as silicon oxide, silicon nitride or phosphorus silicon glass.

It is to be noted that, the method for forming the semiconductor structure provided in the embodiments of the disclosure is similar to that in the above embodiments. The technical features not disclosed in detail in the embodiments of the disclosure refer to the above embodiments for understanding and will not be elaborated herein.

According to the method for forming the semiconductor structure provided in the embodiments of the disclosure, since the periphery of the TSV in the embodiment of the disclosure is provided with at least two protective rings arranged in parallel, the stress generated by the TSV may be resisted through the protective rings, and the semiconductor structure is prevented from being damage and the performance of the semiconductor device is improved.

In several embodiments provided in the disclosure, it should be understood that, the disclosed devices and methods may be implemented in a non-target manner. The device embodiments described above is only schematic, and for example, division of the units is only logic function division, and other division manners may be adopted during practical implementation. For example, multiple units or components may be combined or integrated into another system, or some characteristics may be neglected or not performed. In addition, the components shown or discussed are coupled to each other, or directly coupled.

The above-mentioned units described as separate parts may be or may not be physically separate, and the parts shown as units may be or may not be physical elements, which may be disposed in one place or distributed to a plurality of network elements. Part or all of the units may be selected to achieve the objectives of the solutions of the embodiments according to practical requirements.

The features disclosed in several methods or device embodiments provided by the disclosure may be combined arbitrarily without conflict to obtain new method embodiments or device embodiments.

The above are only some implementations of the embodiments of the disclosure and not intended to limit the scope of protection of the embodiment of the disclosure. Modifications or replacements are apparent to those skilled in the art within the technical scope disclosed by the embodiments of the disclosure, and these modifications or replacements shall fall within the scope of protection of the embodiments of the disclosure. Therefore, the scope of protection of the embodiments of the disclosure should be subject to the appended claims.

What is claimed is:

1. A semiconductor structure, comprising a Through Silicon Via (TSV) and a protective ring disposed outside the TSV,
wherein the protective ring comprises at least two protective layers arranged in parallel and surrounding the TSV;
each of the protective layers comprises a first protective structure and second protective structures disposed surrounding the first protective structure, wherein the first protective structure is a polygonal structure, and a number of sides of the polygonal structure is greater than or equal to 4; and
the second protective structures are disposed on an inner side and an outer side of each corner area of the polygonal structure.

2. The semiconductor structure of claim 1, wherein the second protective structure disposed on the inner side of each corner area of the polygonal structure is in contact with the corner area or separated from the corner area by a first preset distance;
the second protective structure disposed on the outer side of each corner area of the polygonal structure is in contact with the corner area or separated from the corner area by a second preset distance,
wherein the first preset distance or the second preset distance is 0.1 microns to 2 microns.

3. The semiconductor structure of claim 1, wherein the first protective structure has a first preset size in a first direction, the first preset size being 0.3 microns to 2 microns;
the second protective structure has a second preset size in the first direction, the second preset size being 0.1 microns to 2 microns,
wherein the first direction is perpendicular to an extension direction of the TSV.

4. The semiconductor structure of claim 3, wherein the protective ring further comprises connecting layers connecting all of the protective layers,
wherein each connecting layer connects adjacent polygonal structures, and each connecting layer is disposed in a projection area of each corner area of the polygonal structure.

5. The method of claim 4, wherein the polygonal structures of the at least two protective layers have projection areas in the extension direction of the TSV coincided with one another; and
a projection area of the connecting layer in the extension direction of the TSV is located in a projection area of two adjacent protective layers in the extension direction of the TSV.

6. The semiconductor structure of claim 4, further comprising a metal conductive structure,
wherein the metal conductive structure comprises at least two metal layers and at least one contact hole connecting two adjacent metal layers; and the metal layers and the contact hole are alternately distributed along the extension direction of the TSV.

7. The semiconductor structure of claim 6, wherein part of the protective layers of the protective ring and the metal layers are formed simultaneously in a same process step; and the connecting layers of the protective ring and the contact hole are formed simultaneously in a same process step.

8. The semiconductor structure of claim 7, further comprising a buried metal layer and an active device formed in the buried metal layer,
wherein the protective ring further comprises a protective layer formed simultaneously with the buried metal layer in a same process step and a protective layer formed simultaneously with a gate conductive layer of the active device in a same process step.

9. The semiconductor structure of claim 8, wherein the part of protective layers comprise a same material as the metal layer;
the protective layer formed simultaneously with the buried metal layer comprises the same material as the buried metal layer;
the protective layer formed simultaneously with the gate conductive layer comprises a same material as the gate conductive layer; and
the material of the connecting layer is same as a material filling the contact hole.

10. The semiconductor structure of claim 4, further comprising a covering layer,
wherein the covering layer at least covers the TSV and the protective ring.

11. The semiconductor structure of claim 4, wherein a gap is provided between an outer wall of the TSV and an inner wall of the protective ring; and a size of the gap is between 1 micron and 10 microns.

12. A method for forming a semiconductor structure, comprising:
forming a protective ring, wherein the protective ring comprises at least two protective layers arranged in parallel, each of the protective layers comprises a first protective structure and second protective structures disposed surrounding the first protective structure, wherein the first protective structure is a polygonal structure, a number of sides of the polygonal structure is greater than or equal to 4, and the second protective structures are disposed on an inner side and an outer side of each corner area of the polygonal structure;
forming a Through Silicon Via (TSV) on the inner side of the protective ring, to enable the protective ring to surround the TSV.

13. The method of claim 12, wherein the protective ring is formed by:
sequentially forming at least two polygonal structures;
forming the second protective structures each being in contact with a respective one of the corner areas or spaced at a first preset distance from the corner area on an inner side of the corner area of each of the polygonal structures; and
forming the second protective structures each being in contact with a respective one of the corner areas or spaced at a second preset distance from the corner area on an outer side of the corner area,
wherein the first preset distance or the second preset distance is 0.1 microns to 2 microns.

14. The method of claim 12, further comprising:
forming connecting layer connecting all of the protective layers in a projection area of each corner area of the polygonal structure, wherein each connecting layer connects adjacent polygonal structures.

15. The method of claim 13, further comprising:
forming connecting layer connecting all of the protective layers in a projection area of each corner area of the polygonal structure, wherein each connecting layer connects adjacent polygonal structures.

16. The method of claim 12, further comprising:
forming a metal conductive structure while forming the protective ring, wherein the metal conductive structure comprises at least two metal layers and at least one contact hole connecting two adjacent metal layers; and the metal layers and the contact hole are alternately distributed along the extension direction of the TSV.

17. The method of claim 16, wherein forming the metal conductive structure while forming the protective ring comprises:
simultaneously forming part of protective layers of the protective ring and the metal layers of the metal conductive structure in a same process step; and
simultaneously forming the connecting layers of the protective ring and the contact hole of the metal conductive structure in a same process step.

18. The method of claim 17, wherein the semiconductor structure also comprises an active device disposed in a buried metal layer; and the method further comprises:
simultaneously forming a protective layer of the protective ring and a gate conductive layer of the active device in a same process step.

19. The method of claim 16, wherein the semiconductor device further comprises a covering layer; and the method further comprises:
forming the covering layer, wherein the covering layer at least covers the TSV and the protective ring.

20. The method of claim 17, wherein the semiconductor device further comprises a covering layer; and the method further comprises:
forming the covering layer, wherein the covering layer at least covers the TSV and the protective ring.
